(19) United States
(12) Patent Application Publication
(10) Pub. No.: US 2026/0310292 A1
(43) Pub. Date: Oct. 8, 2026

(54) DEEP LEARNING ASSISTED TEXTILE SENSOR MATRIX FOR CO-ADAPTIVE HUMAN-ROBOT COLLABORATION

(71) Applicant: Purdue Research Foundation, West Lafayette, IN (US)

(72) Inventors: Tian Li, West Lafayette, IN (US); Pengfei Deng, Lafayette, IN (US); Yang Meng, West Lafayette, IN (US)

(73) Assignee: Purdue Research Foundation, West Lafayette, IN (US)

(21) Appl. No.: 19/640,029

(22) Filed: Apr. 6, 2026

Related U.S. Application Data
(60) Provisional application No. 63/783,489, filed on Apr. 4, 2025.

(51) Int. Cl. G06F 3/01; B25J 9/16; G06N 3/02; H10D 62/10

(52) U.S. Cl. CPC G06F 3/014; B25J 9/1689; G06F 3/017; G06N 3/02; H10D 62/106

(57) ABSTRACT

A textile-based sensing system is disclosed that includes a textile substrate formed from interlaced semiconducting textile fibers and metal fibers. Intersections between the semiconducting textile fibers and the metal fibers define a plurality of non-ohmic junctions configured to generate electrical signals in response to mechanical stimuli applied to the textile substrate. The plurality of non-ohmic junctions collectively form a distributed textile sensor matrix. One or more processing devices receive electrical signals generated by the textile sensor matrix and process the signals using a trained model configured to compensate for variability arising from non-conformal contact between the textile substrate and a user. Based on analysis of spatiotemporal patterns in the electrical signals, the trained model classifies at least one of a user interaction or an object interaction. The classification is used to interface with an electromechanical system to cause interaction-dependent control.

### CROSS REFERENCE TO RELATED APPLICATIONS

This application claims the benefit of U.S. Provisional Application No. 63/783,489 filed Apr. 4, 2025, the entirety of which is herein incorporated by reference.

### TECHNICAL FIELD

This disclosure relates to textile sensing and, in particular, to textile sensing with machine learning.

### BACKGROUND

Wearable sensing systems and smart textiles have been developed in a variety of forms to enable detection of human motion, gesture, and physical interaction. Existing approaches commonly incorporate discrete electronic sensors, such as resistive, capacitive, or piezoelectric elements, into garments, gloves, or other wearable substrates. Such systems are often used for applications including gesture recognition, human-computer interaction, robotics, rehabilitation, and virtual or augmented reality interfaces.

However, conventional wearable sensing systems frequently rely on rigid or packaged sensor components, external wiring, or mechanically constrained mounting arrangements. These approaches can limit flexibility, comfort, and durability, and may interfere with natural human movement. In addition, many existing systems require tight or well-calibrated contact between sensors and the user's body in order to achieve reliable signal quality, making them sensitive to misalignment, looseness, or textile deformation that commonly occur during real-world use.

Some textile-based sensing approaches embed conductive or functional fibers into fabrics to form sensing structures distributed across a garment. While such approaches improve wearability and coverage, many rely on ohmic or resistive sensing mechanisms that require external power sources and can be susceptible to drift, noise, or cross-talk between sensing elements. Other textile systems focus primarily on energy harvesting or simple contact detection and are not configured to extract higher-level interaction information, such as distinguishing between different gestures or object interactions.

Separately, machine-learning techniques have been applied to wearable sensing data to classify gestures or activities based on patterns observed in sensor signals. These approaches typically assume relatively stable sensor placement and conformal contact, and often require extensive calibration or per-user tuning. As a result, performance can degrade when sensors are loosely fitted, when garments shift on the body, or when contact conditions vary over time. Moreover, many existing systems perform sensing and classification without directly integrating the results into closed-loop control of physical systems, limiting their usefulness in interactive applications.

Accordingly, there remains a need for textile-based sensing systems that combine high wearability and flexibility with robust interaction sensing under non-ideal contact conditions, and that can translate sensed interactions into meaningful, interaction-dependent control of electromechanical systems. There is further a need for systems that leverage distributed sensing across textiles, generate electrical signals directly from mechanical interaction, and employ learning-based techniques to reliably interpret spatiotemporal interaction patterns without requiring rigid sensor placement or extensive calibration.

### BRIEF DESCRIPTION OF THE DRAWINGS

The embodiments may be better understood with reference to the following drawings and description. The components in the figures are not necessarily to scale. Moreover, in the figures, like-referenced numerals designate corresponding parts throughout the different views.

FIG. 1 illustrates a first example of a textile-based sensing system.

FIG. 2 illustrates a flow chart for textile sensor matrix logic of the system according to some embodiments.

FIG. 3 is a block diagram illustrating an example system for textile-based interaction sensing and control.

FIG. 4 illustrates a second example of a textile-based sensing system.

### DETAILED DESCRIPTION

Modern human-robot collaboration systems increasingly require wearable interfaces that can reliably sense human motion and physical interaction while operating under real-world conditions. A key technical challenge in such systems is minimizing motion-induced artifacts arising from both the human body and associated robotic components, while maintaining comfort and long-term usability. These requirements drive the development of conformable, wearable, and widely accessible interfaces that operate in close physical proximity to both humans and robots.

To improve conformability between sensing devices and the human body, two general strategies have been explored. One approach employs soft materials having elastic moduli comparable to human tissue, such as hydrogels, elastomers, and conjugated polymers, enabling intimate contact with the skin. Another approach reduces the thickness of devices fabricated from relatively stiff materials, such as metals or graphene, so that the effective mechanical stiffness more closely matches that of biological tissue. Both strategies have been demonstrated in applications including bioelectronic interfaces, electronic skins, health monitoring devices, and human-machine interaction systems.

However, devices relying on ultrathin structures or soft materials often suffer from limited mechanical robustness. Such devices are susceptible to damage during everyday use, including external impacts, friction, repeated deformation, or tensile stress, which can compromise long-term reliability. In addition, achieving stable sensor—skin coupling typically requires tight or adhesive-based attachment, which can reduce breathability and adversely affect wearing comfort, especially during prolonged use.

Textiles, including garments, clothing, and footwear commonly worn in daily life, provide an alternative substrate for wearable sensing systems. Textiles inherently offer breathability, mechanical compliance, flexibility, and user comfort, making them well-suited for long-term deployment. By integrating functional components directly into textile structures, electronic textiles can serve as scalable platforms for wearable and human-robot interaction systems. Various manufacturing techniques, including weaving, knitting, braiding, embroidery, and other textile processes, enable functional fibers to be incorporated into fabrics at scale. Such approaches have been explored for integrating functions such as energy harvesting, sensing, and display elements into textiles.

Despite these advantages, achieving both high sensing performance and user comfort in textile-based systems remains a significant technical challenge. A loose-fitting textile enhances breathability and comfort but results in non-conformal contact between the textile and the body. Differences in mechanical properties between textiles and human skin, along with garment motion and deformation, introduce variability and motion-induced artifacts that degrade sensing accuracy and signal stability. Conversely, tighter-fitting textiles can improve contact stability but at the expense of comfort, mobility, and long-term wearability.

Several textile-based sensing systems have attempted to address these challenges using machine-learning techniques to interpret sensor data. While such approaches can improve sensitivity or classification accuracy, many rely on low-density sensor networks, rigid sensor patches, or resistive sensing mechanisms that require external power sources. Other systems function primarily as isolated sensing patches rather than distributed textile sensor matrices, limiting spatial resolution and underutilizing the sensing potential of the textile substrate. In addition, many existing machine-learning-based wearable systems assume stable sensor placement and conformal contact, making them poorly suited for loosely worn textiles that shift during normal use.

Accordingly, there remains a need for textile-based sensing systems that provide high-density, spatially distributed sensing while maintaining comfort, flexibility, and durability. There is further a need for systems that generate electrical signals directly from mechanical interaction at the textile level, reducing dependence on external power sources. There is also a need for learning-based signal processing techniques that explicitly compensate for variability arising from non-conformal contact, textile deformation, and motion-induced artifacts. Finally, there is a need to translate sensed interactions into actionable, interaction-dependent control of electromechanical systems, enabling closed-loop human-robot collaboration.

In accordance with these needs, the systems and methods described herein provide a textile substrate comprising interlaced semiconducting textile fibers intersecting with metal fibers to form a plurality of non-ohmic junctions arranged as a distributed textile sensor matrix. Mechanical stimuli applied to the textile substrate generate electrical signals at the non-ohmic junctions, which collectively encode spatiotemporal interaction patterns across the textile. One or more processing devices receive the electrical signals and process them using a trained model configured to compensate for variability arising from non-conformal contact between the textile and a user. Based on analysis of the spatiotemporal patterns, the trained model classifies at least one of a user interaction or an object interaction. The classification is then used to interface with an electromechanical system to cause interaction-dependent control, thereby enabling closed-loop operation that integrates textile-based sensing, learning-based interpretation, and controlled physical response. Additional and alternative technical advancements over exiting approaches are described herein.

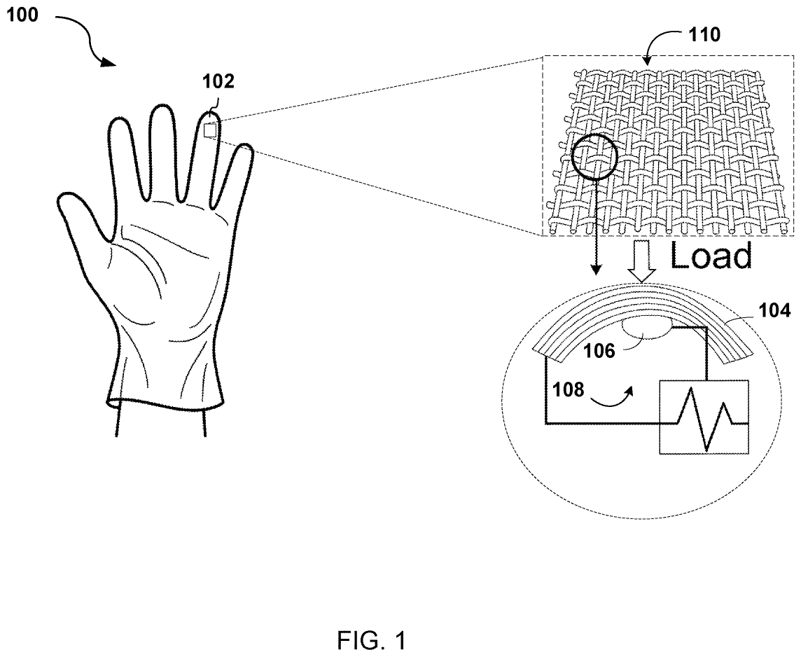

FIG. 1 illustrates a first example of a textile-based sensing system 100. The textile based sensing system 100 may include a textile substrate 102. The textile substrate 102 may include fibers. The fibers may include semiconducting fibers 104 and metal fibers 106.

The semiconducting fibers 104 may include to textile fibers that are configured to exhibit semiconducting electrical behavior when incorporated into a textile substrate, including the ability to support charge transport and to form non-ohmic electrical junctions with intersecting conductive or metal fibers. Such fibers retain mechanical properties suitable for textile integration, including flexibility, breathability, and compatibility with textile manufacturing techniques, while exhibiting electrical characteristics intermediate between insulating and metallic conductors. Semiconducting behavior may arise from the intrinsic properties of the fiber material itself, or from modification of an otherwise non-semiconducting textile fiber through surface functionalization, coating, infiltration, or composite formation, such that the fiber operates as a semiconducting element within the textile substrate and participates in rectifying or asymmetric charge transport in response to mechanical stimulation.

In certain embodiments, the semiconducting textile fibers comprise textile fibers that are rendered semiconducting through integration with a conductive or semiconducting material, including conductive polymers, organic semiconductors, doped polymers, or polymer composites having semiconducting behavior. In some implementations, natural or synthetic textile fibers, such as cellulose-based fibers, are functionalized with a conductive polymer to form semiconducting textile fibers capable of forming non-ohmic, metal-semiconductor junctions with intersecting metal fibers. Non-limiting examples of conductive or semiconducting polymers include poly(3,4-ethylenedioxythiophene):polystyrene sulfonate (PEDOT:PSS), polyaniline, polypyrrole, and derivatives or combinations thereof. In these embodiments, the semiconducting textile fibers function as flexible semiconductor elements within a distributed textile sensor matrix, enabling mechanically induced modulation of charge transport at fiber intersections while preserving textile functionality.

The metal fibers 106 formed predominantly of a metallic material and configured for integration into a textile substrate. Metal fibers exhibit high electrical conductivity relative to semiconducting textile fibers and are capable of functioning as electrodes or conductive counterparts within the textile substrate. When interlaced with semiconducting textile fibers, metal fibers participate in the formation of non-ohmic electrical junctions, including rectifying junctions, by virtue of differences in electronic properties such as work function. The metal fibers 106 retain sufficient mechanical flexibility, durability, and processability to be incorporated into woven, knitted, braided, or embroidered textile structures without substantially impairing textile form or function.

In certain embodiments, the metal fibers 106 comprise elemental metals or metal alloys commonly used in conductive textiles, including aluminum, copper, silver, nickel, stainless steel, or combinations and alloys thereof. In some implementations, metal fibers intersect semiconducting textile fibers at multiple locations within the textile substrate, with each intersection forming a metal-semiconductor contact that functions as a non-ohmic junction. For example, aluminum fibers may be interlaced with semiconducting textile fibers to form interfaces at which mechanically induced modulation of charge transport occurs, enabling generation of an electrical output in response to pressure, friction, or relative motion. In these embodiments, the metal fibers function as electrically conductive components within a distributed textile sensor matrix, cooperating with the semiconducting textile fibers to enable sensing, charge transport, and rectifying behavior while preserving textile flexibility and wearability.

The semiconducting fibers 104 may and the metal fibers 106 may together form intersections which provide a junction 108. A junction 108 refers to a region within a textile substrate at which two or more fibers physically contact, overlap, cross, or are brought into sufficient proximity to permit electrical interaction between the fibers. An intersection may be formed by weaving, knitting, braiding, embroidery, or other textile fabrication techniques that bring fibers into repeated or distributed contact within the textile substrate. At such intersections, electrical coupling may occur through direct contact, pressure-induced contact, or contact mediated by surface coatings or functionalized layers, allowing electrical signals to be generated or modulated in response to mechanical stimuli applied to the textile substrate.

In certain embodiments, intersections between the semiconducting fibers 104 and metal fibers 106 form non-ohmic electrical junctions, in which charge transport across the intersection exhibits rectifying or asymmetric current-voltage behavior. Such non-ohmic behavior may arise from differences in electronic properties between the intersecting fibers, including work-function mismatch, band alignment, or interfacial barrier formation. In some implementations, the intersection functions as a metal-semiconductor junction, including a Schottky-type junction, in which the effective barrier height and charge transport characteristics are modulated by mechanical stimuli such as pressure, friction, or relative motion at the fiber interface. In these embodiments, each intersection operates as an electrically active sensing element within a distributed textile sensor matrix, contributing to the generation of electrical outputs that encode spatiotemporal information associated with user interactions or object interactions.

The junctions on the textile substrate may collectively form a distributed textile sensor matrix 110. The sensor matrix 110 may include an arrangement of multiple sensing elements that are spatially distributed across a substrate and configured to collectively generate electrical signals associated with physical interactions occurring at different locations on the substrate. The sensing elements of the sensor matrix may be arranged in a regular or irregular pattern and may be sampled, processed, or analyzed individually or in combination to capture both spatial and temporal variations in mechanical stimuli, including pressure, force, friction, or motion. In the context of a textile substrate, the sensor matrix is integrated into the textile structure itself and maintains the flexibility, conformability, and wearability characteristic of textile materials.

In certain embodiments, the sensor matrix comprises a distributed textile sensor matrix formed by a plurality of electrically active intersections between semiconducting textile fibers and metal fibers interlaced within the textile substrate. In such embodiments, each intersection functions as an individual sensing element by forming a non-ohmic electrical junction whose electrical output is modulated by mechanical stimuli applied to the textile substrate. Electrical signals generated by the plurality of sensing elements collectively encode spatiotemporal patterns that reflect how mechanical interactions evolve across different regions of the textile substrate over time. These spatiotemporal patterns may be processed by one or more processing devices, including by a trained model, to classify user interactions or object interactions and to support interaction-dependent control of an electromechanical system. The distributed textile sensor matrix may span selected regions of the textile substrate, such as fingertip, finger, or palm regions of a glove, or may extend across substantially the entire textile substrate, enabling scalable, high-density sensing without compromising textile form or function.

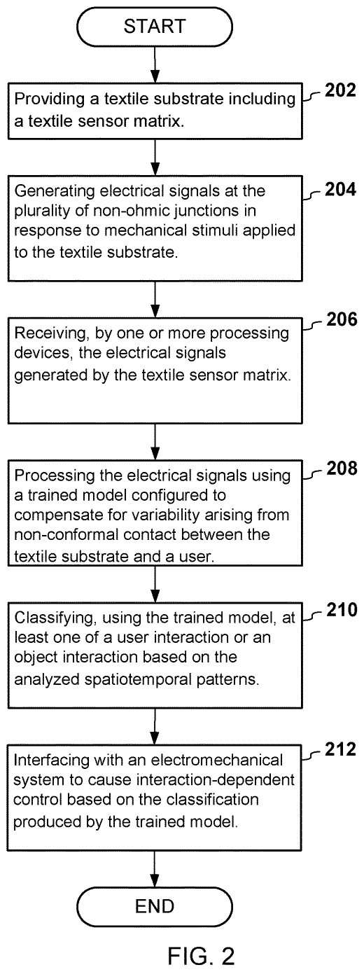

FIG. 2 illustrates a flow chart for textile sensor matrix logic of the system according to some embodiments. In operation, the operations includes providing a textile substrate (202) having interlaced fibers including semiconducting textile fibers intersecting with metal fibers, wherein intersections between the semiconducting textile fibers and the metal fibers form a plurality of non-ohmic junctions. The textile substrate may be formed from interlaced fibers arranged by weaving, knitting, braiding, embroidery, or combinations thereof. The semiconducting textile fibers may comprise conductive polymers, organic semiconductors, doped polymers, or polymer composites having semiconducting behavior, including polymers such as PEDOT:PSS, polyaniline, polypyrrole, or derivatives thereof. The metal fibers may comprise aluminum, copper, silver, nickel, stainless steel, or alloys thereof. At each intersection, differences in electronic properties between the semiconducting textile fiber and the metal fiber give rise to a non-ohmic electrical junction, including in some embodiments a rectifying junction resulting from a work-function mismatch, such as a Schottky-type junction. The plurality of such intersections collectively define a distributed textile sensor matrix that is physically integrated into the textile substrate and spatially distributed across a sensing region of the textile.

The distributed textile sensor matrix functions as a plurality of electrically active sensing elements embedded within the textile itself, with each intersection of a semiconducting textile fiber and a metal fiber forming an individual sensing element. Because the sensing elements are formed at fiber intersections rather than as discrete packaged sensors, the resulting matrix preserves the flexibility, conformability, and wearability of the textile substrate while enabling dense spatial sensing over selected regions or substantially the entire textile. In some embodiments, the distributed textile sensor matrix comprises at least 50 sensing elements per square centimeter and is scalable by increasing a number of interlaced fibers without altering the geometry of individual sensing elements.

The operations further includes generating electrical signals at the plurality of non-ohmic junctions in response to mechanical stimuli applied to the textile substrate (204). Mechanical stimuli may include pressure, contact, friction, deformation, relative motion, or combinations thereof arising from interaction between the textile substrate and a user or an external object.

At each non-ohmic junction, mechanical stimulation modulates the electrical characteristics of the junction, resulting in an electrical output that varies as a function of the local mechanical interaction. In some embodiments, each non-ohmic junction exhibits rectifying current-voltage behavior. The electrical output may comprise one or more of an open-circuit voltage signal or a short-circuit current signal, and in some implementations the electrical output is generated without supplying an external power source to the textile substrate, such that mechanical energy applied to the textile is converted into electrical energy. Because the non-ohmic junctions are distributed across the textile substrate, mechanical interactions occurring at different locations give rise to corresponding electrical signals that collectively reflect both the spatial distribution and temporal evolution of the applied stimuli.

The operations further include receiving, by one or more processing devices, the electrical signals generated by the distributed textile sensor matrix (206). The electrical signals may be received as voltage signals, current signals, or combinations thereof corresponding to multiple sensing elements sampled over time.

The one or more processing devices may receive electrical signals from some or all of the non-ohmic junctions and may perform signal acquisition, aggregation, buffering, or synchronization operations to organize the received signals into a form suitable for subsequent analysis. In some implementations, the received signals collectively represent a time-varying, spatially distributed signal set corresponding to mechanical interactions across the textile substrate.

The operations further includes processing the electrical signals using a trained model configured to compensate for variability arising from non-conformal contact between the textile substrate and a user (208). In particular, the trained model analyzes spatiotemporal patterns in the electrical signals generated by the distributed textile sensor matrix.

Rather than relying on individual sensing elements in isolation, the trained model processes the electrical signals collectively to capture correlations across multiple sensing elements and across successive time intervals. The spatiotemporal patterns may comprise pressure distributions across multiple sensing elements over time. Through this analysis, the trained model learns characteristic spatiotemporal patterns associated with different interaction conditions while reducing sensitivity to signal variability caused by loose fitting, shifting contact, fabric deformation, or motion-induced artifacts inherent to wearable textile systems. The trained model may comprise a neural network, including one or more of a recurrent neural network, a long short-term memory (LSTM) network, a convolutional neural network (CNN), a convolutional LSTM (ConvLSTM), or combinations thereof.

The trained model may be trained using labeled data obtained under loose-fitting or non-conformal textile contact conditions, such that the model learns representations that are robust to changes in contact geometry, textile movement, and user-dependent variability. In some embodiments, the trained model is further configured to adapt classification performance across different users or across different electromechanical systems without retraining from scratch. In this manner, reliable interpretation of textile-based sensor signals is achieved without requiring rigid sensor placement, tight mechanical coupling, or per-user mechanical calibration.

The operations further include classifying, using the trained model, at least one of a user interaction or an object interaction based on the analyzed spatiotemporal patterns (210). User interactions may include hand gestures, postures, or motions of the user, while object interactions may include grasping, manipulating, contacting, or otherwise interacting with an external object.

The classification is performed based on learned differences in the spatial distribution and temporal evolution of the electrical signals across the distributed textile sensor matrix. In some embodiments, the trained model distinguishes between different objects based on differences in spatiotemporal pressure signatures associated with interactions involving those objects.

The operations further includes interfacing with an electromechanical system to cause interaction-dependent control based on the classification produced by the trained model (212). The classification output may be provided to one or more controllers, processors, or control modules associated with the electromechanical system, which may comprise a robotic system, a robotic hand or manipulator, a prosthetic device, a haptic interface, or a teleoperation system.

Based on the classified user interaction or object interaction, control actions may be initiated, selected, or modified such that the behavior of the electromechanical system depends on the identified interaction. The electromechanical system may include one or more controllable components such as actuators, motors, joints, end-effectors, haptic elements, or other driven mechanical elements, along with associated controllers, drive electronics, and communication interfaces. The classification output produced by the trained model may be provided to a control module of the electromechanical system, which interprets the classification as a control input, command selector, or mode-selection signal.

In example implementations, the control actions may cause physical movement or actuation of components of the electromechanical system. For instance, when the classified interaction corresponds to a user hand gesture, the control action may cause a robotic hand or manipulator to mirror the gesture through coordinated actuation of joints or fingers. When the classified interaction corresponds to an object interaction, the control action may initiate, modify, or terminate object manipulation, such as adjusting grip force, repositioning an end effector, or executing a predefined task sequence associated with the identified object. In other embodiments, the control action may activate haptic feedback elements, update a control mode in a teleoperation system, or modify operational parameters of a prosthetic device. In this manner, the method enables closed-loop operation in which textile-based sensing, learning-based interpretation of spatiotemporal contact patterns, and interaction-dependent control of physical system components are functionally integrated.

This approach offers numerous advantages over existing approaches. For example, conventional textile sensing and wearable interaction systems typically rely on discrete resistive or capacitive sensors, rigidly mounted sensing elements, or tightly fitted sensor assemblies that assume stable and repeatable contact conditions, thereby limiting performance under deformation, motion, or loose wear. Other approaches employing flexible or textile-based sensors often focus on raw signal generation or threshold-based detection and lack mechanisms for reliable interpretation of distributed signals under variable contact conditions. Still other systems apply machine-learning techniques to gesture or interaction recognition but assume calibrated sensor placement and uniform contact, making them sensitive to motion-induced artifacts and unsuitable for loosely worn textiles. In contrast, the present approach integrates a distributed textile sensor matrix formed by electrically active, non-ohmic fiber junctions with a learning-based signal processing framework that explicitly leverages spatiotemporal patterns across the textile substrate and is trained to remain robust under non-conformal contact conditions. By treating the textile itself as a spatially and temporally expressive sensing surface and combining this with a trained model that compensates for variability inherent to wearable fabrics, the disclosed system enables reliable interaction classification without requiring rigid sensor placement, mechanical constraint, or per-user calibration, and further supports interaction-dependent control of electromechanical systems in a manner not achievable with prior sensing or learning approaches.

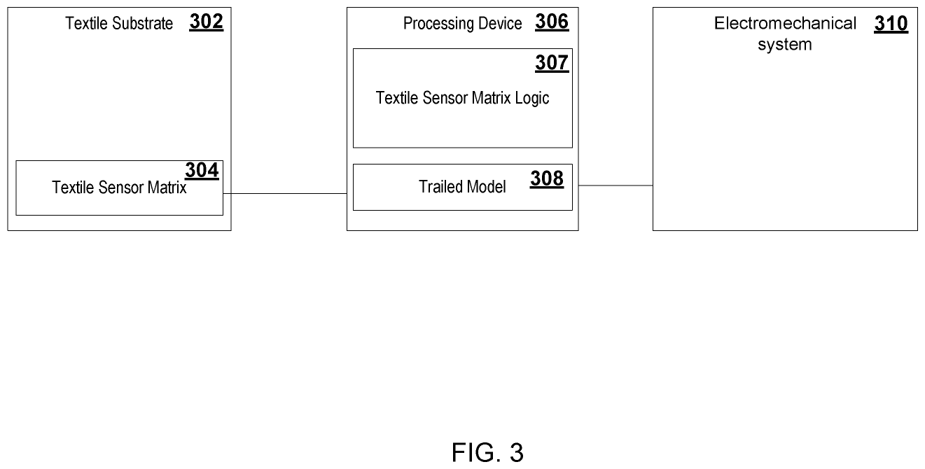

FIG. 3 is a block diagram illustrating an example system for textile-based interaction sensing and control. The system includes a textile substrate 302 comprising interlaced semiconducting textile fibers and metal fibers that form a plurality of non-ohmic junctions arranged as a distributed textile sensor matrix 304. The distributed textile sensor matrix 304 is integrated into the textile substrate 302 and includes a plurality of sensing elements that generate electrical signals in response to mechanical stimuli applied to the textile substrate, such as pressure, friction, deformation, or relative motion arising from interaction with a user or an external object. In some embodiments, the distributed textile sensor matrix 304 includes conductive pathways, conductive yarns, traces, or electrode structures integrated into the textile substrate 302 that electrically couple the sensing elements to one or more connection points or interfaces.

Electrical signals generated by the distributed textile sensor matrix 304 are provided to one or more processing devices 306. The communication between the textile sensor matrix 304 and the processing device 306 may be implemented through wired connections, such as conductive textile traces, embroidered conductors, flexible leads, or connectors coupled to the textile substrate, or through wireless communication interfaces. The one or more processing devices 306 may include one or more processors, microcontrollers, signal-conditioning circuits, analog-to-digital converters, memory, or communication interfaces, and are configured to receive, buffer, aggregate, or otherwise process electrical signals generated by the textile sensor matrix. The electrical signals may comprise voltage signals, current signals, or combinations thereof, and may be sampled over time from multiple sensing elements to form spatiotemporal signal data.

The processing device 306 processes the received electrical signals using the textile sensor matrix logic 307 (discussed in reference to FIG. 2) and a trained model 308. The trained model 308 is configured to analyze spatiotemporal patterns in the electrical signals and to compensate for variability arising from non-conformal contact between the textile substrate and the user, such as loose fitting, textile deformation, shifting contact locations, or motion-induced artifacts. The trained model 308 may comprise a neural network, including any one or more of a recurrent neural network, a long short-term memory (LSTM) network, a convolutional neural network (CNN), a convolutional LSTM (ConvLSTM), or combinations thereof. Based on the analyzed spatiotemporal patterns, the trained model 308 generates a classification identifying at least one of a user interaction or an object interaction.

In some embodiments, the one or more processing devices 306 are located locally with respect to the textile substrate 302. For example, the processing device 306 may be integrated into or physically coupled to the textile substrate as a wearable electronics module, edge computing device, or embedded controller, and may perform signal acquisition, preprocessing, feature extraction, and classification locally. Local processing may enable low-latency operation, reduced communication bandwidth, or continued operation when network connectivity is limited or unavailable.

In other embodiments, the one or more processing devices 306 are located remotely from the textile substrate 302. For example, electrical signals or processed signal data generated by the distributed textile sensor matrix 304 may be transmitted to a remote processing system, such as a cloud-based computing platform, server, or remote workstation, where the trained model 308 is executed. In such embodiments, the remote processing device may perform computationally intensive operations, model evaluation, or data aggregation across multiple users or sessions.

In still other embodiments, the processing functionality is distributed across both local and remote processing devices. For example, a local processing device coupled to the textile substrate 302 may perform initial signal conditioning, preprocessing, or partial inference using the trained model 308, while a remote processing device performs additional analysis, classification refinement, model updating, or coordination with one or more electromechanical systems 310. Communication between local and remote processing devices may occur over wired or wireless communication links, and the trained model 308 or portions thereof may be executed locally, remotely, or partitioned across multiple processing devices.

The classification output generated by the trained model 308 is provided from the processing device 306 to an electromechanical system 310. The electromechanical system 310 may include one or more controllable components such as actuators, motors, joints, end-effectors, haptic elements, prosthetic components, or other driven mechanical elements, along with associated controllers, drive electronics, and communication interfaces. The electromechanical system 310 interprets the classification output as a control input, command selector, or operational mode indicator, and performs control actions that depend on the identified interaction.

In example implementations, the interaction-dependent control actions performed by the electromechanical system 310 may include mirroring a classified user gesture through coordinated actuation of a robotic hand or manipulator, initiating or modifying object manipulation actions such as adjusting grip force or repositioning an end effector, executing a predefined task associated with a classified object interaction, or activating haptic feedback or prosthetic responses corresponding to the interaction. In this manner, the system of FIG. 3 enables closed-loop operation in which textile-based sensing at the textile substrate 302, learning-based interpretation of spatiotemporal interaction patterns by the trained model 308, and interaction-dependent control of physical components of the electromechanical system 310 are functionally integrated.

Experimental Evaluations/Results: In experimental evaluations, example implementations of the disclosed textile-based sensing system were constructed to assess sensing performance, robustness under non-conformal contact, and interaction-dependent control capability. The system included a textile substrate comprising interlaced semiconducting textile fibers and metal fibers forming a plurality of non-ohmic junctions arranged as a distributed textile sensor matrix. The textile substrate was configured to be worn loosely or subjected to relative motion, deformation, or shifting contact during use, so as to evaluate system performance under non-ideal wearable conditions.

Mechanical stimuli, including pressure, contact, sliding motion, and object manipulation, were applied to the textile substrate during testing. The non-ohmic junctions generated electrical signals in response to the applied mechanical stimuli, and the electrical signals were collected from multiple sensing elements distributed across the textile substrate. The resulting signals exhibited spatial and temporal variation corresponding to different interaction locations and interaction dynamics, forming spatiotemporal signal patterns representative of user interactions and object interactions occurring across the textile surface.

The electrical signals generated by the distributed textile sensor matrix were processed by one or more processing devices using a trained model configured to compensate for variability arising from non-conformal contact between the textile substrate and a user. In particular, the trained model analyzed spatiotemporal patterns across multiple sensing elements rather than relying on individual sensing elements in isolation. Experimental results demonstrated that the trained model was able to extract consistent interaction representations despite variations in garment fit, textile deformation, and motion-induced artifacts that occurred during use.

In example tests involving repeated user gestures and object interactions performed under varying wearing conditions, the trained model reliably classified user interactions and object interactions based on the analyzed spatiotemporal patterns. Classification performance was maintained across multiple trials in which the textile substrate shifted relative to the user or was subjected to deformation, indicating that the learning-based processing effectively compensated for non-conformal contact and signal variability inherent to wearable textile systems.

The classification outputs generated by the trained model were further used to interface with an electromechanical system to cause interaction-dependent control. In particular, classification results were provided to a control module of the electromechanical system as control inputs or command selectors. In response to classified interactions, the electromechanical system performed corresponding control actions, including mirroring user gestures, initiating or modifying object manipulation, or executing predefined task sequences associated with the classified interactions. Experimental operation demonstrated closed-loop behavior in which textile-based sensing, learning-based interpretation of spatiotemporal interaction patterns, and physical actuation of system components were functionally integrated.

Overall, these experimental results demonstrate that the disclosed textile-based sensing system is capable of generating meaningful electrical signals directly from mechanical interaction at a textile interface, reliably classifying interactions under non-conformal contact conditions using a trained model, and translating classification results into interaction-dependent control of an electromechanical system. The results confirm the suitability of the disclosed approach for wearable and human-robot interaction applications requiring comfort, flexibility, robustness to motion-induced variability, and closed-loop control.

The logic illustrated in the flow diagrams may include additional, different, or fewer operations than illustrated. The operations illustrated may be performed in an order different than illustrated. The system 100 may be implemented with additional, different, or fewer components than illustrated.

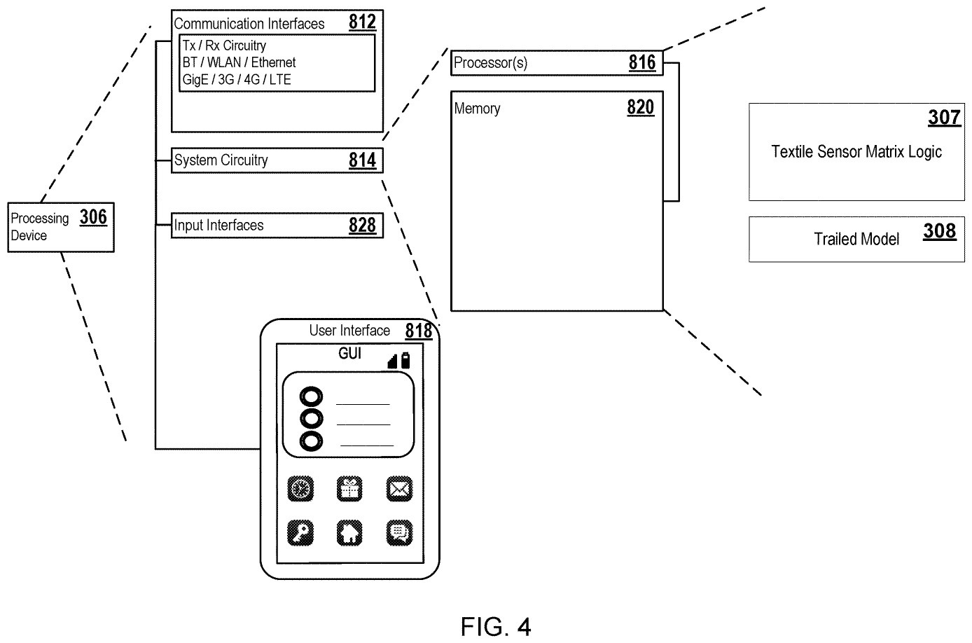

FIG. 4 illustrates a second example of the system 100. The system 100 may include the processing device 306. The processing device may include, or interface with, communication interfaces 812, input interfaces 828 and/or system circuitry 814. The system circuitry 814 may include a processor 816 or multiple processors. Alternatively or in addition, the system circuitry 814 may include memory 820.

The processor 816 may be in communication with the memory 820. In some examples, the processor 816 may also be in communication with additional elements, such as the communication interfaces 812, the input interfaces 828, and/or the user interface 818. Examples of the processor 816 may include a general processor, a central processing unit, logical CPUs/arrays, a microcontroller, a server, an application specific integrated circuit (ASIC), a digital signal processor, a field programmable gate array (FPGA), and/or a digital circuit, analog circuit, or some combination thereof.

The processor 816 may be one or more devices operable to execute logic. The logic may include computer executable instructions or computer code stored in the memory 820 or in other memory that when executed by the processor 816, cause the processor 816 to perform the operations of the textile sensor matrix logic 307, the trained model 308, and/or any other operation described herein. The computer code may include instructions executable with the processor 816.

The memory 820 may be any device for storing and retrieving data or any combination thereof. The memory 820 may include non-volatile and/or volatile memory, such as a random access memory (RAM), a read-only memory (ROM), an erasable programmable read-only memory (EPROM), or flash memory. Alternatively or in addition, the memory 820 may include an optical, magnetic (hard-drive), solid-state drive or any other form of data storage device. The memory 820 may include instructions which cause the processor to perform the operations of the textile sensor matrix logic 307, the trained model 308, and/or any other operation described herein

The user interface 818 may include any interface for displaying graphical information. The system circuitry 814 and/or the communications interface(s) 812 may communicate signals or commands to the user interface 818 that cause the user interface to display graphical information. Alternatively or in addition, the user interface 818 may be remote to the processing device 306 and the system circuitry 814 and/or communication interface(s) may communicate instructions, such as HTML, to the user interface to cause the user interface to display, compile, and/or render information content. In some examples, the content displayed by the user interface 818 may be interactive or responsive to user input. For example, the user interface 818 may communicate signals, messages, and/or information back to the communications interface 812 or system circuitry 814.

The system 100 may be implemented in many different ways. In some examples, the system 100 may be implemented with one or more logical components. For example, the logical components of the system 100 may be hardware or a combination of hardware and software. The logical components may include the textile sensor matrix logic 307, the trained model 208, the processing device, or any component or subcomponent of the system 100 used to conduct the operations described herein. In some examples, each logic component may include an application specific integrated circuit (ASIC), a Field Programmable Gate Array (FPGA), a digital logic circuit, an analog circuit, a combination of discrete circuits, gates, or any other type of hardware or combination thereof. Alternatively or in addition, each component may include memory hardware, such as a portion of the memory 820, for example, that comprises instructions executable with the processor 816 or other processor to implement one or more of the features of the logical components. When any one of the logical components includes the portion of the memory that comprises instructions executable with the processor 816, the component may or may not include the processor 816. In some examples, each logical component may just be the portion of the memory 820 or other physical memory that comprises instructions executable with the processor 816, or other processor(s), to implement the features of the corresponding component without the component including any other hardware. Because each component includes at least some hardware even when the included hardware comprises software, each component may be interchangeably referred to as a hardware component.

Some features are shown stored in a computer readable storage medium (for example, as logic implemented as computer executable instructions or as data structures in memory). All or part of the system and its logic and data structures may be stored on, distributed across, or read from one or more types of computer readable storage media. Examples of the computer readable storage medium may include a hard disk, a flash drive, a cache, volatile memory, non-volatile memory, RAM, flash memory, or any other type of computer readable storage medium or storage media. The computer readable storage medium may include any type of non-transitory computer readable medium, such as a volatile memory, a non-volatile memory, ROM, RAM, or any other suitable storage device.

The processing capability of the system may be distributed among multiple entities, such as among multiple processors and memories, optionally including multiple distributed processing systems. Parameters, databases, and other data structures may be separately stored and managed, may be incorporated into a single memory or database, may be logically and physically organized in many different ways, and may implemented with different types of data structures such as linked lists, hash tables, or implicit storage mechanisms. Logic, such as programs or circuitry, may be combined or split among multiple programs, distributed across several memories and processors, and may be implemented in a library, such as a shared library (for example, a dynamic link library (DLL).

All of the discussion, regardless of the particular implementation described, is illustrative in nature, rather than limiting. For example, although selected aspects, features, or components of the implementations are depicted as being stored in memory(s), all or part of the system or systems may be stored on, distributed across, or read from other computer readable storage media, for example, secondary storage devices such as hard disk, flash memory drives, and the like. Moreover, the various logical units, circuitry and screen display functionality is but one example of such functionality and any other configurations encompassing similar functionality are possible.

The respective logic, software or instructions for implementing the processes, methods and/or techniques discussed above may be provided on computer readable storage media. The functions, acts or tasks illustrated in the figures or described herein may be executed in response to one or more sets of logic or instructions stored in or on computer readable media. The functions, acts or tasks are independent of the particular type of instructions set, storage media, processor or processing strategy and may be performed by software, hardware, integrated circuits, firmware, micro code and the like, operating alone or in combination. Likewise, processing strategies may include multiprocessing, multitasking, parallel processing and the like. In one example, the instructions are stored on a removable media device for reading by local or remote systems. In other examples, the logic or instructions are stored in a remote location for transfer through a computer network or over telephone lines. In yet other examples, the logic or instructions are stored within a given computer and/or central processing unit (“CPU”).

Furthermore, although specific components are described above, methods, systems, and articles of manufacture described herein may include additional, fewer, or different components. For example, a processor may be implemented as a microprocessor, microcontroller, application specific integrated circuit (ASIC), discrete logic, or a combination of other type of circuits or logic. Similarly, memories may be DRAM, SRAM, Flash or any other type of memory. Flags, data, databases, tables, entities, and other data structures may be separately stored and managed, may be incorporated into a single memory or database, may be distributed, or may be logically and physically organized in many different ways. The components may operate independently or be part of a same apparatus executing a same program or different programs. The components may be resident on separate hardware, such as separate removable circuit boards, or share common hardware, such as a same memory and processor for implementing instructions from the memory. Programs may be parts of a single program, separate programs, or distributed across several memories and processors.

A second action may be said to be “in response to” a first action independent of whether the second action results directly or indirectly from the first action. The second action may occur at a substantially later time than the first action and still be in response to the first action. Similarly, the second action may be said to be in response to the first action even if intervening actions take place between the first action and the second action, and even if one or more of the intervening actions directly cause the second action to be performed. For example, a second action may be in response to a first action if the first action sets a flag and a third action later initiates the second action whenever the flag is set.

To clarify the use of and to hereby provide notice to the public, the phrases “at least one of <A>, <B>, . . . and <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed.

While various embodiments have been described, it will be apparent to those of ordinary skill in the art that many more embodiments and implementations are possible. Accordingly, the embodiments described herein are examples, not the only possible embodiments and implementations.

What is claimed is:

1. A textile-based sensing system, comprising:
a textile substrate comprising interlaced fibers including a plurality of semiconducting textile fibers intersecting with a plurality of metal fibers;
wherein intersections between the semiconducting textile fibers and the metal fibers define a plurality of non-ohmic junctions configured to produce an electrical output in response to a mechanical stimulus applied to the textile substrate;
wherein the plurality of non-ohmic junctions collectively form a distributed textile sensor matrix;
and one or more processing devices configured to:
receive electrical signals generated by the textile sensor matrix;
classify, using a trained model configured to compensate for variability arising from non-conformal contact between the textile substrate and a user, the electrical signals as at least one of a user interaction or an object interaction based on spatiotemporal patterns in the electrical signals; and
interface with an electromechanical system to cause interaction-dependent control based on the classification.

2. The textile-based sensing system of claim 1,
wherein the semiconducting textile fibers comprise a conductive polymer, an organic semiconductor, a doped polymer, or a polymer composite having semiconducting behavior.

3. The textile-based sensing system of claim 2,
wherein the semiconducting textile fibers comprise a polymer selected from PEDOT:PSS, polyaniline, polypyrrole, or derivatives thereof.

4. The textile-based sensing system of claim 1,
wherein the metal fibers comprise aluminum, copper, silver, nickel, stainless steel, or alloys thereof.

5. The textile-based sensing system of claim 1,
wherein each non-ohmic junction exhibits rectifying current-voltage behavior resulting from a work-function mismatch between the semiconducting textile fibers and the metal fibers.

6. The textile-based sensing system of claim 5,
wherein the non-ohmic junctions comprise Schottky-type junctions.

7. The textile-based sensing system of claim 1,
wherein the interlaced fibers are formed by weaving, knitting, braiding, embroidery, or combinations thereof.

8. The textile-based sensing system of claim 1,
wherein each intersection of a semiconducting textile fiber and a metal fiber forms an individual sensing element of the distributed textile sensor matrix.

9. The textile-based sensing system of claim 1,
wherein the distributed textile sensor matrix comprises between 50 and 10,000 sensing elements per square centimeter.

10. The textile-based sensing system of claim 1,
wherein the electrical output generated by the non-ohmic junctions is produced without an external power source.

11. The textile-based sensing system of claim 1,
wherein the spatiotemporal patterns comprise pressure distributions across multiple sensing elements over time.

12. The textile-based sensing system of claim 1,
wherein the electromechanical system comprises a robotic system.

13. A method for textile-based interaction sensing and control, comprising:
providing a textile substrate comprising interlaced fibers including semiconducting textile fibers intersecting with metal fibers, wherein intersections between the semiconducting textile fibers and the metal fibers form a plurality of non-ohmic junctions arranged as a distributed textile sensor matrix;
generating, at the plurality of non-ohmic junctions, electrical signals in response to mechanical stimuli applied to the textile substrate;
receiving, by one or more processing devices, electrical signals generated by the distributed textile sensor matrix;
processing the electrical signals using a trained model configured to compensate for variability arising from non-conformal contact between the textile substrate and a user, wherein the trained model analyzes spatiotemporal patterns in the electrical signals;
classifying, using the trained model, at least one of a user interaction or an object interaction based on the spatiotemporal patterns; and
interfacing with an electromechanical system to cause interaction-dependent control based on the classification.

14. The method of claim 13, wherein the non-ohmic junctions exhibit rectifying current-voltage behavior resulting from a work-function mismatch between the semiconducting textile fibers and the metal fibers.

15. The method of claim 13, wherein generating the electrical signals is performed without supplying an external power source to the textile substrate.

16. The method of claim 13, wherein the trained model comprises a neural network selected from a recurrent neural network, a long short-term memory (LSTM) network, a convolutional neural network (CNN), a convolutional LSTM (ConvLSTM), or combinations thereof.

17. The method of claim 13, wherein the trained model is trained using labeled data obtained under loose-fitting or non-conformal textile contact conditions.

18. The method of claim 13, wherein the user interaction comprises a hand gesture.

19. The method of claim 13, wherein the object interaction comprises grasping, manipulating, or contacting an object.

20. The method of claim 13, wherein the trained model distinguishes between different objects based on differences in spatiotemporal pressure signatures.
